(19) United States
(12) Patent Application Publication
(10) Pub. No.: US 2023/0035032 A1
(43) Pub. Date: Feb. 2, 2023

(54) SEMICONDUCTOR PACKAGE INCLUDING BUMP STRUCTURES WITH DIFFERENT SHAPES

(71) Applicant: SAMSUNG ELECTRONICS CO., LTD., SUWON-SI (KR)

(72) Inventors: SUNJAE KIM, SEOUL (KR); SEUNGHOON YEON, SUWON-SI (KR)

(21) Appl. No.: 17/745,666

(22) Filed: May 16, 2022

(30) Foreign Application Priority Data
Aug. 2, 2021 (KR) 10-2021-0101526

(51) Int. Cl. H01L 23/00; H01L 23/498; H01L 25/065

(52) U.S. Cl. CPC H01L 24/14; H01L 24/17; H01L 23/49816; H01L 25/0657; H01L 2224/119; H01L 2224/1403; H01L 2224/73204; H01L 2225/06513

(57) ABSTRACT

A semiconductor package includes; a first semiconductor chip and a second semiconductor chip connected by bump structures, wherein the bump structures include first bump structures having a first shape and second bump structures having a second shape different from the first shape, and each of the bump structures includes a first pillar layer associated with the first semiconductor chip and a second pillar layer associated with the second semiconductor chip.

### CROSS-REFERENCE TO RELATED APPLICATION

This application claims priority under 35 U.S.C. § 119 to Korean Patent Application No. 10-2021-0101526 filed on Aug. 2, 2021 in the Korean Intellectual Property Office, the subject matter of which is hereby incorporated by reference in its entirety.

### BACKGROUND

The inventive concept relates generally to semiconductor packages, and more particularly, to semiconductor packages including bump structure(s).

As the electronics industry rapidly advances and consumer demands increase, contemporary and emerging electronic devices must provide expanded functionality, reduced power consumption, and/or reduced physical size. Accordingly the semiconductor chips included in such electronic devices face similar demands. Thus, semiconductor chips often include connection terminals having a very fine pitch. That is, connection terminals (e.g., bump structures) having a very fine size are required in order to mount high-capacity semiconductor chip(s) within the increasing scarce area of contemporary and emerging semiconductor packages. Furthermore, interval(s) between adjacent (or proximate) bump structures included in a semiconductor package are continuously being reduced.

### SUMMARY

Embodiments of the inventive concept provide semiconductor packages including bump structures having different shapes. Such differing shape bump structures enhance electrical characteristic(s) and improves overall reliability of the semiconductor package by reducing the possibility of short circuiting between adjacent bump structures during certain semiconductor fabrication process(es) (e.g., an over-pressing condition between semiconductor substrates).

According to an aspect of the inventive concept, there is provided a semiconductor package including; a first semiconductor chip and a second semiconductor chip stacked on the first semiconductor chip The first semiconductor chip may include; a first substrate including a top surface and a bottom surface, first through vias extending through the first substrate, first bump pads on the top surface of the first substrate and respectively connected to the first through vias, a first wiring layer on the bottom surface of the first substrate and connected to the first through vias, and first pillar layers respectively on the first bump pads. the second semiconductor chip may include; a second substrate including a bottom surface, second connection pads on the bottom surface of the second substrate, and second pillar layers respectively on the second connection pads and vertically aligned with the first pillar layer. Bump structures may connect the first semiconductor chip and the second semiconductor chip, wherein the bump structures include first bump structures having a first shape and second bump structures having a second shape different from the first shape, and each of the bump structures includes a one of the first pillar layers and one of the second pillar layers.

According to an aspect of the inventive concept, there is provided a semiconductor package including; a logic chip and a memory chip stacked on the logic chip. the logic chip ay include; a first substrate including a top surface and a bottom surface, first through vias extending through the first substrate, first bump pads on the top surface of the first substrate and respectively connected to the first through vias, a first wiring layer on the bottom surface of the first substrate and connected to the first through vias, and first pillar layers respectively on the first bump pads. The memory chip may include; a second substrate including a bottom surface, second connection pads on the bottom surface of the second substrate, and second pillar layers respectively on the second connection pads and vertically aligned with the first pillar layers. Bump structures may be disposed between the logic chip and the memory chip, wherein the bump structures include first bump structures having a first shape and providing electrical connection between the logic chip and the memory chip, and second bump structures having a second shape different from the first shape and providing heat transfer from at least one of the logic chip and the memory chip, and each of the bump structures includes a one of the first pillar layers and one of the second pillar layers.

According to an aspect of the inventive concept, there is provided a semiconductor package including a first semiconductor chip and a second semiconductor chip stacked on the first semiconductor chip. The first semiconductor chip may include; a first substrate including a top surface and a bottom surface, first through vias extending through the first substrate, first bump pads on the top surface of the first substrate and respectively connected to the first through vias, a first passivation layer on the top surface of the first substrate and selectively exposing respective portions of the first bump pads through first open holes and second open holes larger than the first open holes, a first wiring layer on the bottom surface of the first substrate and connected to the first through vias, first seed layers on exposed portions of the first bump pads and portions of the first passivation layer, and first pillar layers respectively on the first seed layers. The second semiconductor chip may include; a second substrate including a bottom surface, second connection pads on the bottom surface of the second substrate, a second passivation layer on the bottom surface of the second substrate and selectively exposing respective portions of the connection pads, second seed layers on exposed portions of the second connection pads and portions of the second passivation layer, and second pillar layers respectively on the second seed layers. Bump structures may connect the first semiconductor chip and the second semiconductor chip, wherein the bump structures include first bump structures having a first shape defined by the first open holes and second bump structures having a second shape defined by the second open holes, and each of the bump structures includes a one of the first pillar layers and one of the second pillar layers.

### BRIEF DESCRIPTION OF THE DRAWINGS

Embodiments of the inventive concept may be more clearly understood upon consideration of the following detailed description together with the accompanying drawings in which:

FIG. 1A is a plan (or top-down) view illustrating a semiconductor package according to embodiments of the inventive concept, FIG. 1B is a cross-sectional view taken along line X-X′ of FIG. 1A, FIG. 1C is an enlarged cross-sectional view of a region ‘CC’ indicated in FIG. 1B, and FIG. 1D is a corresponding plan view of FIG. 1C (hereafter collectively, “FIGS. 1A to 1D”);

FIGS. 2, 3, 4 and 5 are respective cross-sectional views illustrating various semiconductor packages according to embodiments of the inventive concept;

FIG. 6 is a flowchart summarizing in one example a method of manufacturing a semiconductor package according to embodiments of the inventive concept;

FIGS. 7A, 7B, 7C,7D, 7E, 7F and 7G (hereafter collectively, “FIGS. 7A to 7G”) are related cross-sectional views illustrating in one example a method of manufacturing a semiconductor package according to embodiments of the inventive concept; and

FIG. 8 is a block diagram illustrating one possible configuration of a semiconductor package according to embodiments of the inventive concept.

### DETAILED DESCRIPTION

Throughout the written description and drawings, like reference numbers and labels are used to denote like or similar elements, components, method steps and/or features. Throughout the written description certain geometric terms may be used to highlight relative relationships between elements, components and/or features with respect to certain embodiments of the inventive concept. Those skilled in the art will recognize that such geometric terms are relative in nature, arbitrary in descriptive relationship(s) and/or directed to aspect(s) of the illustrated embodiments. Geometric terms may include, for example: height/width; vertical/horizontal; top/bottom; higher/lower; closer/farther; thicker/thinner; proximate/distant; above/below; under/over; upper/lower; center/side; surrounding; overlay/underlay; etc.

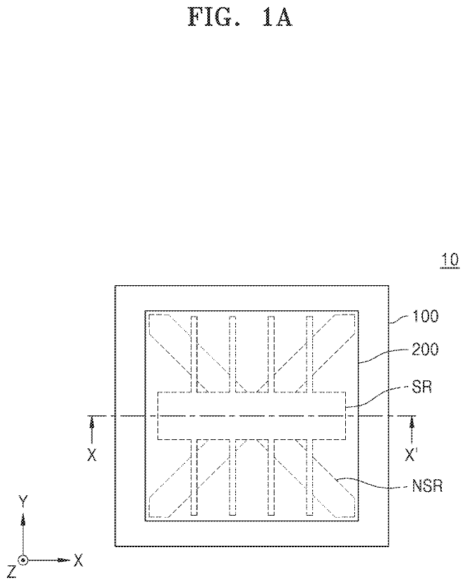

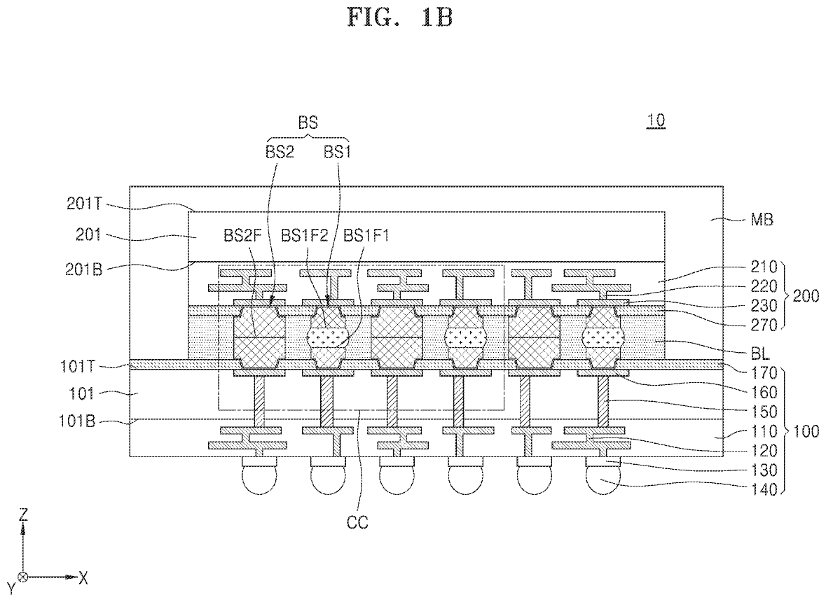

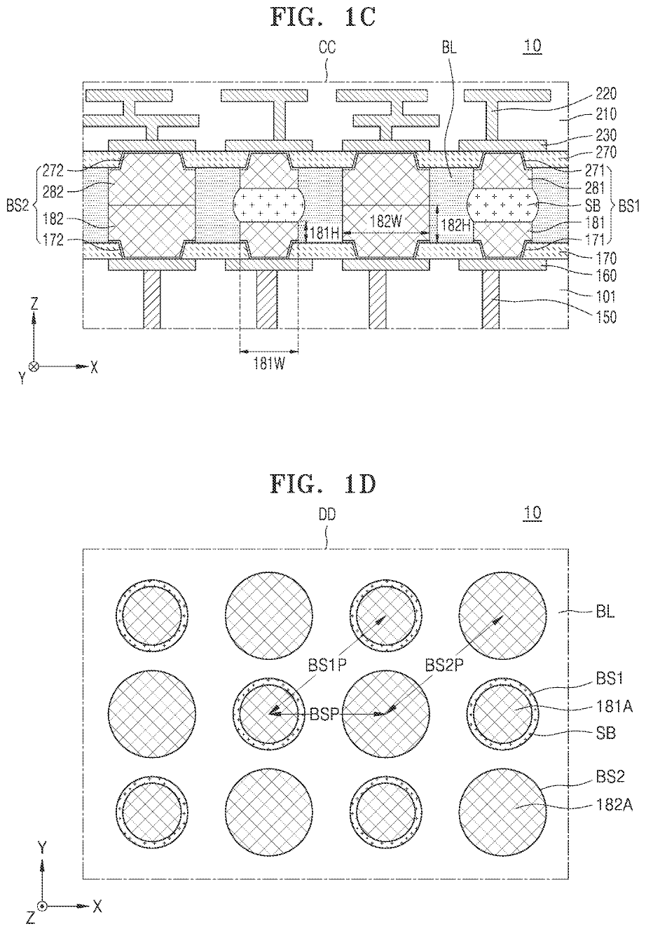

Figure (FIG.) 1A is a plan view illustrating a semiconductor package according to embodiments of the inventive concept, FIG. 1B is a cross-sectional view taken along line X-X′ of FIG. 1A, FIG. 1C is an enlarged cross-sectional view of a region ‘CC’ indicated in FIG. 1B, and FIG. 1D is a corresponding plan view of FIG. 1C.

Referring to FIGS. 1A to 1D, the semiconductor package 10 may include a first semiconductor chip 100, a second semiconductor chip 200, a molding member MB, and a plurality of bump structures BS (hereafter, “bump structures”) used to electrically connect the first semiconductor chip 100 and the second semiconductor chip 200.

Each of the first semiconductor chip 100 and the second semiconductor chip 200 may be a memory chip or a logic chip. The first semiconductor chip 100 and the second semiconductor chip 200 be the same kind of chip, or different kinds of chips. For example, one or both of the first semiconductor chip 100 and the second semiconductor chip 200 may be memory chips; one or both of the first semiconductor chip 100 and the second semiconductor chip 200 may be logic chips; or one of the first semiconductor chip 100 and the second semiconductor chip 200 may be a memory chip and the other one of the first semiconductor chip 100 and the second semiconductor chip 200 may be a logic chip.

In this regard, the memory chip may be a volatile memory chip (e.g., a dynamic random access memory (RAM) (DRAM) or a static RAM (SRAM)) or a nonvolatile memory chip (a phase-change RAM (PRAM), a magneto-resistive RAM (MRAM), a ferroelectric RAM (FeRAM), a resistive RAM (RRAM), etc.).

The logic chip may be (e.g.,) a microprocessor, an analog device, a digital signal processor, etc.

The first semiconductor chip 100 may include a first substrate 101 (e.g., a wafer) having a top surface 101T and an opposing bottom surface 101B, a first semiconductor device layer 110, a first wiring layer 120, first connection pads 130, first connection terminals 140, first through vias 150, first bump pads 160, a first passivation layer 170, first seed layers 171 and 172, and first pillar layers 181 and 182.

Here, the top surface 101T may be an inactive surface and the bottom surface 101B may be an active surface, wherein the first semiconductor device layer 110 may be formed on the bottom surface 101B and the first through vias 150 may extend through the body of the first substrate 101.

The first substrate 101 may include at least one of, for example, silicon (Si), crystalline Si, polycrystalline Si, and amorphous Si. Alternately or additionally, the first substrate 101 may include at least of, for example, germanium (Ge), silicon carbide (SiC), gallium arsenide (GaAs), indium arsenide (InAs), indium phosphide (InP), etc.

The first substrate 101 may have a silicon-on-insulator (SOI) structure. For example, the first substrate 101 may include a buried oxide (BOX) layer. In some embodiments, the first substrate 101 may include a conductive region (e.g., an impurity-doped well or region). Also, the first substrate 101 may include various isolation region(s) and/or structure(s), such as a shallow trench isolation (STI) structure.

The first semiconductor device layer 110 may include the first wiring layer 120 configured to connect various elements, components and/or wiring associated with the first substrate 101. The first wiring layer 120 may include variously arranged metal wiring layer(s) and/or via plug(s). In some embodiments, the first wiring layer 120 may have a multi-layer structure wherein two or more metal wiring layers and/or two or more via plugs are variously stacked.

The first connection pads 130 may be variously arranged under the first semiconductor device layer 110 and electrically connected to the first wiring layer 120 of the first semiconductor device layer 110. The first connection pads 130 may be respectively connected to the first through vias 150 through the first wiring layer 120. Here, each of the first connection pads 130 may include at least one of, for example, aluminum (Al), copper (Cu), nickel (Ni), tungsten (W), platinum (Pt) and gold (Au).

The first connection terminals 140 may be respectively disposed on and directly contact the first connection pads 130. Here, the first connection terminals 140 may be used to variously connect the semiconductor package 10 with one or more external elements and/or components (not shown). For example, the first semiconductor chip 100 may be connected to one or more control signal(s), data signal(s), power signal(s), and/or ground connection(s) through the first connection terminals 140. For example, write data to-be-written (or programmed) to the first semiconductor chip 100 and/or read data retrieved from the first semiconductor chip 100 may be communicated (i.e., transmitted and/or received) to one or more external elements and/or components. The first connection terminals 140 may include a pillar structure, a ball structure, or a solder structure, as ready examples.

The first through vias 150 may pass (or extend) through the first substrate 101 between the bottom surface 101B and the top surface 101T. In this manner, the first wiring layer 120, the first conductive pads, and the first connection terminals 140 may be variously connected to the overlaying bump structures BS. That is, the first connection pads 130 may be electrically connected to the first through vias 150 through the first wiring layer 120. The respective first through vias 150 may have a pillar shape (wholly or in part). In some embodiments, one or more of the first through vias 150 may be a through silicon via (TSV).

The first bump pads 160 may be disposed in electrical contact with first through vias 150 through the top surface 101T of the first substrate 101. Thus, as noted above, the first bump pads 160 may be variously connected to the first wiring layer 120 of the first semiconductor device layer 110 through the first through vias 150. Here, the first bump pads 160 may include at least one of, for example, Al, Cu, Ni, W, Pt, and Au.

The first passivation layer 170 may substantially cover the top surface 101T of the first substrate 101, yet leave exposed at least a portion of each one of the first bump pads 160. The first passivation layer 170 may include at least one of, for example, silicon oxide, silicon nitride, silicon oxynitride, a polymer material (e.g., silicone, epoxy, benzocyclobutene (BCB), polyimide (PI), or polybenzoxazole (PBO)), etc.

Each one of the first pillar layers 181 and 182 may be respectively disposed on and electrically connected to a corresponding one of the first bump pads 160 through a corresponding one of the first seed layers 171 and 172. Here, the first seed layers 171 and 172 may include at least one of, for example, Cu, Ni, titanium (Ti), W, tin (Sn), and silver (Ag). Each of the first seed layers 171 and 172 may function as a seed used to respectively form one of the first pillar layers 181 and 182. That is, assuming that the first pillar layers 181 and 182 are formed using an electro-plating process, the first seed layers 171 and 172 may provide a materials spot (or path) through which electrical current may flow, thereby forming the first pillar layers 181 and 182 on the first seed layers 171 and 172.

The first pillar layers 181 and 182 may include at least one of, for example, Cu, Ni, and Au. In some embodiments, the first pillar layers 181 and 182 may include Cu or a Cu alloy. In this regard, and as described hereafter in some additional detail, each one of the first pillar layers 181 and 182 may respectively form a portion of a corresponding one of the bump structures BS.

The second semiconductor chip 200 may be disposed so that the bottom surface 201B of the second substrate 201 configuring the second semiconductor chip 200 faces the top surface 101T of the first substrate 101 of the first semiconductor chip 100. The second semiconductor chip 200 may be electrically connected to the first semiconductor chip 100 through the bump structure BS disposed between the first semiconductor chip 100 and the second semiconductor chip 200.

Referring to FIG. 1B, the second semiconductor chip 200 may include a second substrate 201, a second semiconductor device layer 210, a second wiring layer 220, second bump pads 230, a second passivation layer 270, second seed layers 271 and 272, and second pillar layers 281 and 282. In this regard, the second semiconductor chip 200 may be understood as including elements that are substantially similar to analogously numbered elements (e.g., 170/270; 230/130; 220/120; 210/110; 171/271; 172/272; 181/281; 182/282, etc.) previously described in relation to the first semiconductor chip 100. Accordingly hereafter, only material differences between the first semiconductor chip 100 and the second semiconductor chip 200 will be highlighted.

The second substrate 201 (e.g., a wafer) may be a semiconductor substrate having a top surface 201T and an opposing bottom surface 201B, wherein the bottom surface 201B may be an active surface and the top surface 201B may be an inactive surface.

The second semiconductor device layer 210 may be formed on (or under) the bottom surface 201B of the second substrate 201. The second bump pads 230 may be disposed on the second semiconductor device layer 210 and may be electrically connected to the second wiring layer 220 of the second semiconductor device layer 210.

The second passivation layer 270 may be formed to substantially cover the bottom surface 201B of the second substrate 201, yet leave exposed at least a portion of each one of the second bump pads 230.

Each one of the second pillar layers 281 and 282 may be disposed on and be electrically connected to a corresponding one of the second bump pads 230 through one of the second seed layers 271 and 272. In this regard, and as described hereafter in some additional detail, each one of the second pillar layers 281 and 282 may respectively form a portion of a corresponding one of the bump structures BS.

Each one of the bump structures BS may extend between, and respectively contact one of the first bump pads 160 and one of the second bump pads 230 to electrically connect at least one of the first bump pads 160 with at least one of the second bump pads 230.

Thus, the second semiconductor chip 200 may receive (and/or provide) at least one control signal(s), power signal(s), data signal(s) and/or ground connections to the first semiconductor chip 100 and/or one or more external elements or components through the various bump structures BS.

In some embodiments, and referring to FIGS. 1B, 1C and 1D, the bump structures BS may include one or more first bump structures BS1 and one or more second bump structures BS2 that may be distinguished by their different shapes. For example, each first bump structure BS1 may be formed by bonding together a first pillar layer 181 and a second pillar layer 281 using (e.g.,) a solder ball SB. In contrast, each second bump structure BS2 may be formed by directly bonding together a first pillar layer 182 and a second pillar layer 282. With this configuration, each first bump structure BS1 includes bonding surfaces between different materials (e.g., Cu and solder), whereas each second bump structures BS2 includes a bonding surface between the same material (Cu and Cu). That is, referring to FIG. 1B, each first bump structure BS1 may include two (2) (e.g., an upper and a lower) first bonding interfaces BS1F1 and BS1F2 between different materials (e.g., Cu and solder), whereas each second bump structure BS2 may include one (1) second bonding interface BS2F between the same materials (e.g., Cu and Cu). In this regard, the term “bonding interface” denotes a contact region between either two different materials (e.g., Cu of a first pillar layer or Cu of a second pillar layer and solder of a solder ball), or respective portions of the same material (e.g., Cu of one pillar layer (whether first pillar layer or second pillar layer) and Cu of another pillar layer (whether first pillar layer or second pillar layer)).

Further in this regard, the second bonding interface BS2F associated with a second bump structure BS2 may be substantially disposed at a “midpoint” along a vertical extent of the second bump structure BS2 (e.g., as may be identified in relation to a vertical (or Z) direction). Still further in this regard, a lower first bonding interface BS1F1 associated with the first bump structure BS1 may be disposed a lower level than the second bonding interface BS2F and an upper first bonding interface BS1F2 associated with the first bump structure BS1 may be disposed a higher level than the second bonding interface BS2F. In this context, the term “level” denotes a relative distance (e.g., measured in the vertical direction) from an arbitrarily selected horizontal plane, e.g., a horizontal plane intersecting the second bonding interface BS2F. Accordingly, in some embodiments, no bonding interface associated with a first bump structure BS1 will be disposed at a level as a bonding interface associated with a second bump structure BS2 .

Referring to FIG. 1C, in some embodiments, the first pillar layer 181 of a first bump structure BS1 may have a first width 181W (e.g., a distance measured in a first horizontal (or X) direction). The first pillar layer 182 of a second bump structure BS2 may have a second width 182W. In some embodiments, the first width 181W may be less than the second width 182W. For example, the first width 181W may be range from about 13 μm to about 15 μm and the second width 182W may range from about 50 μm to about 150 μm, but the scope of the inventive concept is not limited thereto. Accordingly, in some embodiments a third width of the second pillar layer 281 associated with the first bump structure BS1 may be less than a fourth width of the second pillar layer 282 associated with the second bump structure BS2.

In some embodiments, a first thickness (or height) 181H (e.g., a distance measured in a the vertical direction from an arbitrarily selected horizontal plane—e.g., a top surface of the first passivation layer 170) of the first pillar layer 181 associated with the first bump structure BS1 may be less than a second thickness 182H of the first pillar layer 182 associated with the second bump structure BS2. For example, the first thickness 181H may range from about 13 μm to about 15 μm and the second thickness 182H may range from about 7 μm to about 9 μm, but the scope of the inventive concept is not limited thereto. Accordingly, a thickness of the second pillar layer 281 of the first bump structure BS1 may be less than a thickness of the second pillar layer 282 of the second bump structure BS2.

Referring to FIG. 1D, in some embodiments, a first planar (or lateral) area 181A of the first pillar layer 181 associated with the first bump structure BS1 may be less than a second planar area 182A of the first pillar layer 182 associated with the second bump structure BS2. Accordingly, a planar area of the second pillar layer 281 of the first bump structure BS1 may be less than a planar area of the second pillar layer 282 of the second bump structure BS2.

In some embodiments, a pitch BSP (or interval) between adjacent ones of the bump structures BS—whether first bump structure BS1 or second bump structure BS2—may be substantially the same. That is, a first pitch BS1P between adjacent first bump structures BS1 may be substantially the same as a second pitch BS2P between adjacent second bump structures BS2.

In some embodiments, a particular pattern (or arrangement) of first bump structure(s) BS1 and second bump structure(s) BS2 may be repeated. For example, as shown in FIG. 1D, the first bump structures BS1 and the second bump structures BS2 may be alternated and off-set by adjacent rows to form a pattern of bump structures BS including each first bump structure BS1 symmetrically surrounded by four (4) second bump structures BS2, and each second bump structure BS2 symmetrically surrounded by four (4) first bump structures BS1. That is, first bump structures BS1 and second bump structures BS2 may be alternatingly arranged in a first arrangement in a first row, and first bump structures BS1 and second bump structures BS2 may be alternatingly arranged in a second arrangement offset from the first arrangement in a second row.

Referring to FIG. 1A, in some embodiments, all of the bump structures BS may be disposed in a defined signal bump region SR between the first substrate 101 and the second substrate 201, such that bump structures BS are disposed in a non-signal-bump region SNR outside the signal bump region SR.

In some embodiments, the first bump structures BS1 may “active bump structures” (e.g., bump structures that communicate one or more electrical signal(s)), whereas the second bump structures BS2 may be “dummy bump structures” (e.g., bump structures that that do not communicate signal(s), but rather facilitate heat transfer). Accordingly, the structure and materials composition of the second bump structures BS2 may be designed with heat transfer and/or heat dissipation properties in mind. For example, assuming that the first semiconductor chip 100 is logic chip, the second bump structures BS2 may be designed and configured to exhaust (or transfer, or discharge) heat in a direction away from the first semiconductor chip 100.

An adhesive layer BL may be disposed between the top surface 101T of the first substrate 101 and the bottom surface 201B of the second substrate 201 and may attach the second semiconductor chip 200 on the first semiconductor chip 100. The adhesive layer BL may directly contact the first semiconductor chip 100 and the second semiconductor chip 200 and may be disposed to surround a plurality of bump structures BS.

Referring to FIG. 1B, in some embodiments, the semiconductor package 10 may further include an adhesive layer BL including (e.g.,) a non-conductive film, such as adhesive resin or flux. In other embodiments, the adhesive layer BL may introduced into the semiconductor package 10 as underfill layer that substantially surrounds sidewalls of the bump structures BS substantially fills spaces between adjacent ones of the bump structures BS.

Referring to FIG. 1B, the molding member MB may be disposed to substantially surround side walls of the second semiconductor chip 200 and portions of the top surface 101T of the first semiconductor chip 100. With this configuration, the molding member MB may protect the semiconductor package 10 from external shocks and/or contamination.

Accordingly, the molding member MB may include an epoxy mold compound or resin. Further, the molding member MB may be formed by process(es) such as compression molding, lamination, screen printing, etc. However, in some embodiments, the molding member MB may surround only one side surface of the second substrate 201 and otherwise expose portions of the top surface 201T of the second substrate 201.

As noted above, semiconductor packages used in contemporary and emerging electronic products should provide high performance and/or large data storage capacity with a minimum of size and weight. In order accomplish this difficult feat, the semiconductor packages according to embodiments of the inventive concept may include a chip-on-wafer structure wherein a first semiconductor chip is vertically stacked on a second semiconductor chip.

Accordingly, the respective thicknesses of the first and second semiconductor chips may be very thin and therefore structurally weak in order to ensure that the size and weight of the overall semiconductor package is acceptable. It follows, therefore, that one or more fabrication process(es) used to effectively stack the first and second semiconductor chips should faithfully address issues such as formation variables, solder wettability, electrical connection and reliability, and structural reliability. As a result of these considerations and others, the nature (e.g., material(s) composition, adhesion properties, etc.) and geometry (e.g., shape, height, width, material(s) composition, etc.) of the bump structures BS are important considerations.

Thus, during the manufacture of a semiconductor package involving process(es) used to compress facing pairs of the first and second semiconductor chips providing bump structure(s) therebetween, when an excessive amount of solder protrudes beyond the boundaries of a defined bump structure, short circuiting may occur as the result of a protruding solder portion contacting another conductive element (e.g., a wiring, pad, another bump structure, etc.).

In minimize the possibility of such short circuiting, semiconductor packages according to embodiments of the inventive concept may include bump structures BS having different shapes, in order to provide different bonding interfaces disposed at different levels. For example, as noted above, a first bump structure BS1 may include a first bonding interface providing at least one Cu layer-to-solder layer connection, while a second bump structure BS2 may include a second bonding interface providing a Cu layer-to-Cu layer connection. Further, in some embodiments, these different type of bonding interfaces may be vertically off-set one from the other. Therefore, the possibility of an extraneous solder protrusion contacting a nearby, conductive element—particularly during, or as the result of a compression condition (e.g., an over-pressing or misalignment of facing substrates)—may be markedly reduced.

Furthermore, certain system-in-package architectures including a logic chip stacked with one or more memory chip(s) may particularly suffer from the generation of potentially harmful thermal energy (or heat). That is, excessive heat generated primarily by the logic chip may adversely affect the performance of memory chip(s).

Thus, some semiconductor packages consistent with embodiments of the inventive concept may include one or more dummy bump structure(s) (e.g., the second bump structure BS2 above) particularly designed and configured to efficiently dissipate heat. In this regard, the planar area of a pillar layer configuring as a dummy bump structure may be greater than a planar area of a pillar layer configuring as a signal bump structure (e.g., the first bump structure BS1 above). As a result, heat transfer and/or heat dissipation properties for semiconductor packages according to embodiments of the inventive concept may be enhanced by the inclusion of dummy bump structures BS2, notwithstanding the densely-integrated and increasingly limited space provided within contemporary and emerging semiconductor packages.

Additionally, many contemporary and emerging semiconductor packages include stacked semiconductor chips, wherein the constituent semiconductor chips may be bonded together using an adhesive layer. However, if an amount (or portion) of an adhesive layer excessively overflows into surrounding region(s), one or more subsequent manufacturing process(es) may be adversely impacted, thereby reducing manufacturing yield.

Thus, some semiconductor packages consistent with embodiments of the inventive concept may include one or more dummy bump structure(s) (e.g., the second bump structure BS2 above) particularly designed and configured to function as spacer(s) that uniformly maintain a defined separation interval between the stacked semiconductor chips. Accordingly, an amount of the adhesive layer BL filling a space between bump structures BS disposed between stacked semiconductor chips may be better predicted, and introduced with better control.

From the foregoing those skilled in the art will recognize that semiconductor packages according to embodiments of the inventive concept provide higher product reliability and improved production yields.

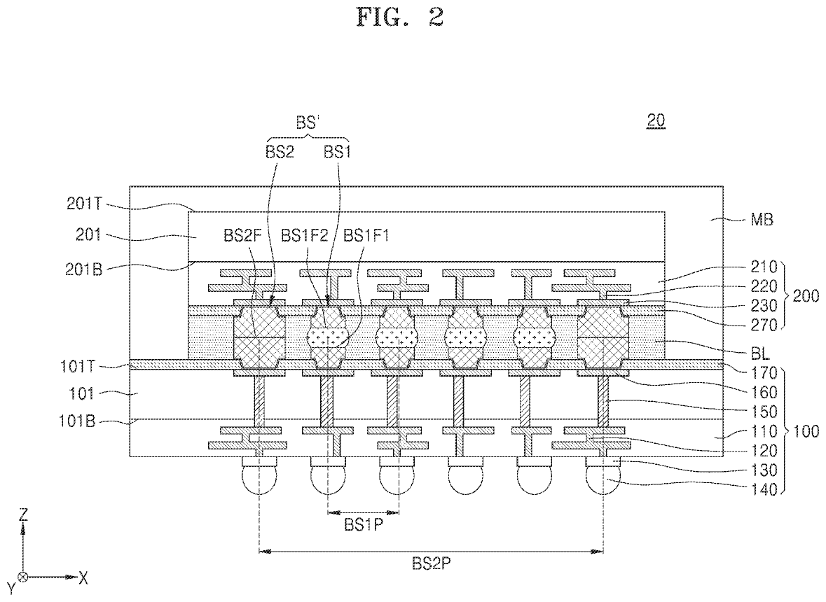

FIGS. 2, 3, 4 and 5 are respective cross-sectional views illustrating various semiconductor packages according to embodiments of the inventive concept.

Only material difference between the embodiments of FIGS. 2, 3, 4, and 5 and those of FIGS. 1A to 1D will be highlighted.

Referring to FIG. 2, a semiconductor package 20 may include the first semiconductor chip 100, the second semiconductor chip 200, and the molding member MB, as well as bump structures BS' that may be used to variously connect the first semiconductor chip 100 and the second semiconductor chip 200.

In the semiconductor package 20, a first pitch BS1P defining a first interval between adjacent first bump structures BS1 may differ from a second pitch BS2P defining a second interval between adjacent second bump structures BS2. For example, an arrangement of first bump structures BS1 may be laterally bracketed in at least one of the first horizontal direction and the second horizontal direction between adjacent second bump structures BS2. In some embodiments, the arrangement of first bump structures BS1 may be substantially surrounded by that second bump structures BS2.

In the semiconductor package 20, the first bump structures BS1 may serve primarily as active bump structures (e.g., to communicate one or more signal(s)), whereas the second bump structures BS2 may serve primarily as dummy bump structures that define a separation space between the first substrate 100 and the second substrate 201. That is, the second bump structures BS2 may serve as spacers that uniformly maintain a defined separation space between the first and second semiconductor chips 100 and 200. Therefore, an amount of the adhesive layer BL used to fill spaces between respective bump structures BS′ may be well controlled within a predictable range.

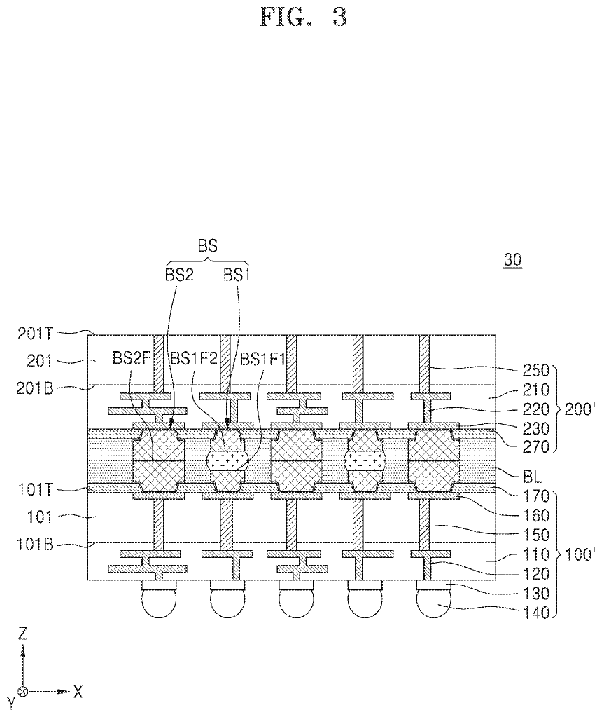

Referring to FIG. 3, a semiconductor package 30 may include a first semiconductor chip 100′, a second semiconductor chip 200′, and bump structures BS that may be used to variously connect the first semiconductor chip 100′ and the second semiconductor chip 200′.

In the semiconductor package 30, a width of the first semiconductor chip 100′ may substantially the same as a width of the second semiconductor chip 200′. Further, the second semiconductor chip 200′ may include second through vias 250 in addition to the second substrate 201, the second semiconductor device layer 210, the second wiring layer 220, the second bump pad 230, the second passivation layer 270, the second seed layers 271 and 272, and the second pillar layers 281 and 282.

In this regard, the second semiconductor device layer 210 may be formed on (or under) the bottom surface 201B of the second substrate 201. The second bump pads 230 may be disposed on the second semiconductor device layer 210 to electrically connect the second wiring layer 220, which in turn, may be connected to the second through vias 250.

In the semiconductor package 30, as before, the first bump structures BS1 may be active bump structures, and the second bump structures BS2 may be dummy bump structures that primarily serve to transfer and/or dissipate heat. In this manner, the second bump structures BS2 may enhance heat transfer and/or heat dissipation properties of the first semiconductor chip 100′ and/or the second semiconductor chip 200′.

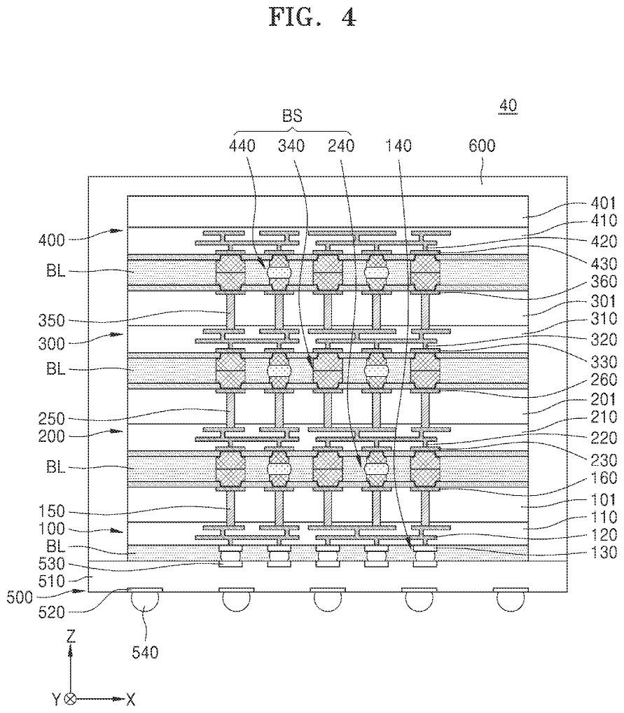

Referring to FIG. 4, a semiconductor package 40 may include a stacked structure of semiconductor chips disposed on a base substrate 500. In the exemplary, illustrated embodiment of FIG. 4. the stacked structure is assumed to include the first semiconductor chip 100, the second semiconductor chip 200, as well as a third semiconductor chip 300, and a fourth semiconductor chip 400 (hereafter collectively, “first to fourth semiconductor chips 100 to 400”) respectively stacked one on top of the other in the vertical direction. However, this is just one example and other stacked structures may include any reasonable number of semiconductor chips.

The first to fourth semiconductor chips 100 to 400 may be variously interconnected with one another and with the based substrate 500 through first to fourth connection terminals 140, 240, 340, and 440. Each of the first to fourth semiconductor chips 100 to 400 may be mechanically attached to a top surface of the base substrate 500 using sequentially disposed adhesive layers BL.

Each of the first to fourth semiconductor chips 100 to 400 may be a memory chip or a logic chip. In some embodiments, all of the first to fourth semiconductor chips 100 to 400 may be a memory chip of one type (e.g., volatile and nonvolatile). In some embodiments, the first to fourth semiconductor chips 100 to 400 may each be a high bandwidth memory (HBM) chip.

In some embodiments, each of the first to fourth semiconductor chips 100 to 400 may be similarly configured to include; a substrate X01, a semiconductor device layer X10, a wiring layer X20, connection pads X30, connection terminals X40, and through vias X50, wherein the variable ‘X’ in this annotation ranges from 1 to 4. However, the fourth semiconductor chip 400, being an uppermost semiconductor chip in the stacked structure, may omit the upper bump pads.

Analogous to the configuration of the first semiconductor chip 100 with the second semiconductor chip 200, the third semiconductor chip 300 may be mounted on a top surface of the second semiconductor chip 200, and the fourth semiconductor chip 400 may be mounted on a top surface of the third semiconductor chip 300. Respective adhesive layers BL may be disposed between the second semiconductor chip 200 and the third semiconductor chip 300, as well as between the fourth connection terminal 440 and the third semiconductor chip 300.

In some embodiments, the base substrate 500 may be a printed circuit board (PCB), wherein the base substrate 500 may include; a substrate body portion 510, bottom pads 520, top pads 530, and a solder resist layer (not shown) formed on a bottom surface and/or a top surface of the substrate body portion 510. Wiring layer(s) (not shown) variously connecting the bottom pads 520 and the top pads 530 may be provided on the bottom surface of the substrate body portion 510, the top surface of the substrate body portion 510 and/or internally within the substrate body portion 510. Here, at least a portion of each one of the bottom pads 520 and the top pads 530 may be exposed through the solder resist layer.

Alternately, the base substrate 500 may be an interposer, wherein the base substrate 500 may include the substrate body portion 510 including a semiconductor material, and the bottom pads 520 and the top pads 530 respectively formed on the bottom surface and the top surface of the substrate body portion 510. The substrate body portion 510 may be formed from (e.g.,) a semiconductor wafer. Wiring layers (not shown) variously connecting the bottom pads 520 and the top pads 530 may be provided on the bottom surface of the substrate body portion 510, the top surface of the substrate body portion 510 and/or internally within the substrate body portion 510. One or more through vias in the substrate body portion 510 (not shown) may be used to connect the bottom pad 520 and the top pad 530.

External connection terminals 540 may be attached on the bottom surface of the base substrate 500 at respective bottom pads 520. Each of the external connection terminals 540 may be a solder ball or a solder bump. The external connection terminals 540 may be used to connect the semiconductor package 40 to an one or more external elements and/or components.

A molding member 600 may be formed to substantially surround the first to fourth semiconductor chips 100 to 400 on the base substrate 500. That is, in some embodiments, the molding member 600 may surround side surfaces of the first to fourth semiconductor chips 100 to 400, as well as side surfaces of the respective adhesive layers BL.

In some embodiments, the molding member 600 may also cover a top surface of an uppermost semiconductor chip in the stacked structure (e.g., the fourth semiconductor chip 400), while in other embodiments, the molding member 600 may leave the top surface of the uppermost semiconductor chip in the stacked structure exposed.

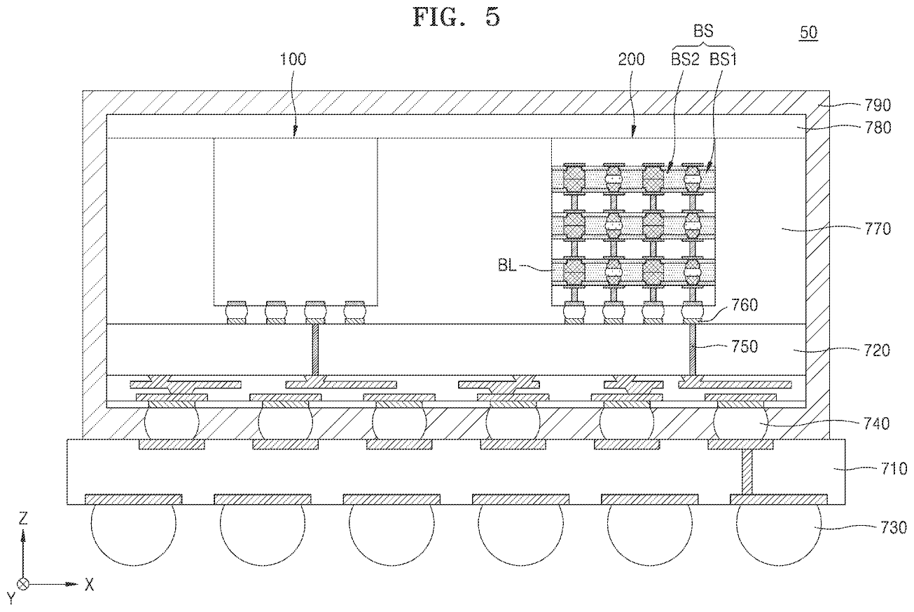

Referring to FIG. 5, a semiconductor package 50 may include a package substrate 710, an interposer 720 disposed on the package substrate 710, as well as the first semiconductor chip 100 and the second semiconductor chip 200 disposed on the interposer 720.

In some embodiments, for example, the package substrate 710 included in the semiconductor package 50 may be formed on at least one of a PCB, a wafer substrate, a ceramic substrate, and a glass substrate.

External connection terminals 730 may be disposed on a bottom surface of the package substrate 710. The semiconductor package 50 may be connected to and mounted on a system board or a module substrate of an electronic product through the external connection terminals 730.

The interposer 720 may include an internal connection terminal 740 connected to a lower portion thereof. The internal connection terminal 740 may be connected to the first semiconductor chip 100 and the second semiconductor chip 200 through a through via 750. Also, first bump pads 760 may be disposed on a top surface of the interposer 720.

In the semiconductor package 50, the first semiconductor chip 100 and the second semiconductor chip 200 may be mounted on the interposer 720, and a molding member 770 may substantially surround the first semiconductor chip 100 and the second semiconductor chip 200. Further, a heat dissipation member 780 may be disposed on the top surface of the first semiconductor chip 100 and/or the top surface of the second semiconductor chip 200.

In some embodiments, the semiconductor package 50 may further include an upper encapsulation layer 790 disposed on a top surface of the heat dissipation member 780.

Within the semiconductor package 50, the first semiconductor chip 100 may be a single logic chip and may be implemented as a microprocessor, a graphics processor, a signal processor, a network processor, a chipset, an audio codec, a video codec, an application processor, or a system on chip. The second semiconductor chip 200 may include an HBM chip where a plurality of slices configure a stack structure.

In the semiconductor package 50, bump structures BS, as previously described in the foregoing embodiments, may be variously included in the second semiconductor chip 200.

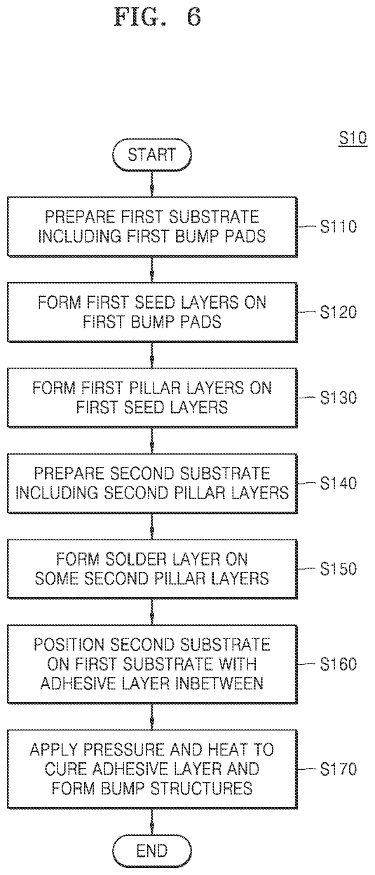

FIG. 6 is a flowchart illustrating a method of manufacturing a semiconductor package, according to an embodiment.

Referring to FIG. 6, the method of manufacturing a semiconductor package may include preparing a first substrate including first bump pads (S110). Here, the first substrate may ultimately be disposed at a lower position within the semiconductor package, and the first bump pads may serve as connection elements in relation to respective bump structures BS and a second semiconductor chip 200. In this regard, portions of the first bump pads may be selectively exposed though a first passivation layer formed on a top surface of the first substrate.

First seed layers may be formed on the exposed portions of the first bump pads (S120), and first pillars layers may be then formed on the first seed layers (S130).

A second substrate including second pillar layers may be prepared (S140). Here, the second substrate may ultimately be disposed at an upper position within the semiconductor package.

A solder layer may be selectively formed on the second pillar layers (S150).

Then, the second substrate may be positioned and aligned with the first substrate with an intervening adhesive layer (S160).

Pressure and heat may then be applied to the positioned first and second substrates to form bump structures electrically connecting the first and second substrates, and to cure the adhesive layer, thereby stably fixing the first and second substrate (S170).

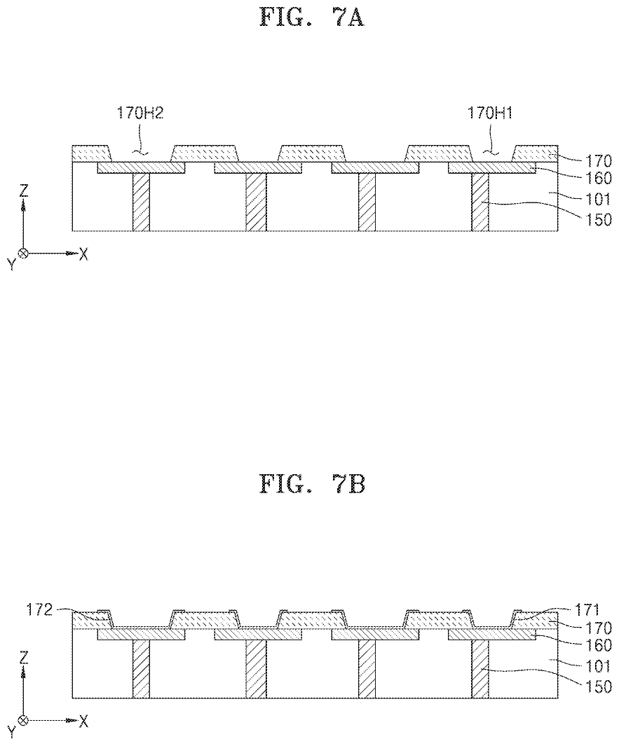

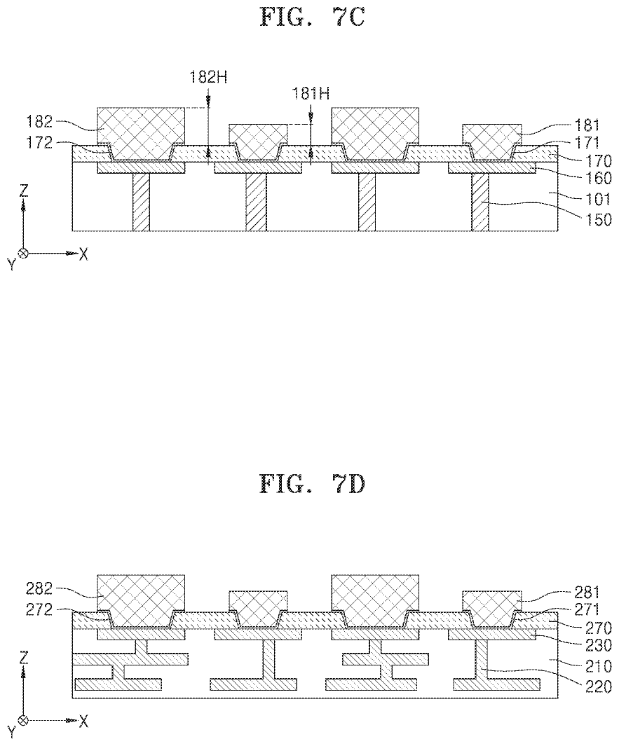

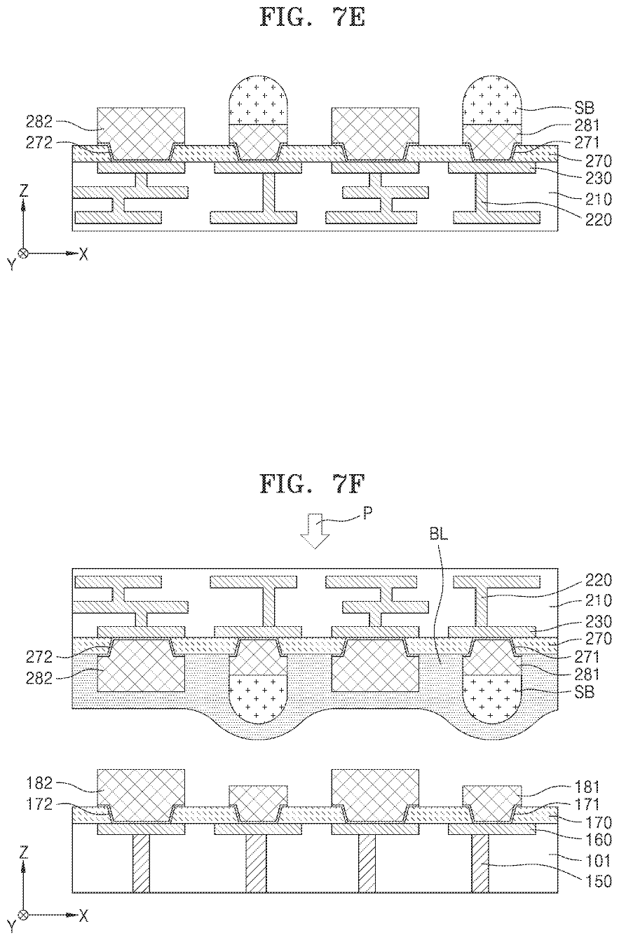

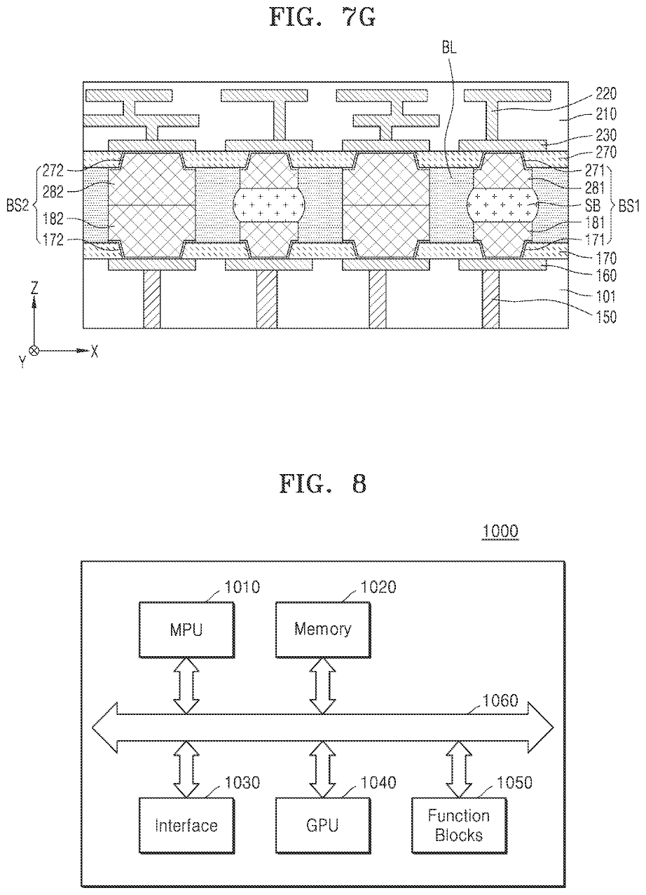

FIGS. 7A to 7G are related cross-sectional view illustrating in one example a method of manufacturing a semiconductor package according to embodiments of the inventive concept. Here, each of FIGS. 7A to 7G may be compared with the region CC illustrated in FIG. 1C.

Referring to FIGS. 1B and 7A, a first substrate 101 is prepared that will ultimately be disposed at a lower portion of a semiconductor package.

First through vias 150 may be formed in the first substrate 101. Generally, process(es) used to form the first through vias 150 may include a via first process, a via middle process, and a via last process. For example, the via last process may form a first semiconductor device layer 110 and a first wiring layer 120 on a bottom surface 101B of the first substrate 101, and then, may form the first through via 150 passing through the first substrate 101 up to the bottom surface 101B from the top surface 101T.

The first bump pads 160 may then be formed on the top surface 101T of the first substrate 101 to respectively contact an exposed upper portion of a corresponding one of the first through vias 150.

The first passivation layer 170 may be formed and patterned to include first open holes 170H1 and second open holes 170H2 respectively exposing a portion of the first bump pads 160. The first passivation layer 170 may be formed as a single-layer insulation layer or a multi-layer insulation layer to cover the top surface 101T of the first substrate 101. In some embodiments, a width of the first open holes 170H1 may be less than a width of the second open holes 170H2.

In this regard the size and geometry of the first open holes 170H1 and second open holes 170H2 may define, at least in some material part, the respective geometry and shapes of the first bump structures and the second bump structures.

Referring to FIGS. 1B and 7B, first seed layers 171 and 172 may be formed on exposed portions of the first bump pads 160.

That is, the first seed layers 171 may be formed on first bump pads 160 exposed through the first open holes 170H1, and the first seed layers 172 may be formed on first bump pads 160 exposed through the second open holes 170H2.

In some embodiments, the first seed layers 171 and 172 may be formed using a chemical vapor deposition (CVD) process or a physical vapor deposition (PVD) process to have a thickness that ranges from about 100□ to about 0.5 μm. The first seed layers 171 and 172 may include at least one of, for example, Cu, Ni, Ti, W, Sn, and Ag.

The first seed layers 171 and 172 may function as a seed for the subsequent formation of the first pillar layers 181 and 182. (See, e.g., FIG. 7C). That is, assuming that the first pillar layers 181 and 182 are formed using an electro-plating process, the first seed layers 171 and 172 may provide a spot or path through which electrical current flows, thereby forming (or growing) the first pillar layers 181 and 182 on the first seed layers 171 and 172.

Referring to FIGS. 1B and 7C, the first pillar layers 181 and 182 may be formed on the first seed layers 171 and 172.

The first pillar layers 181 and 182 may be formed to directly contact top surfaces of the first and second seed layers 171 and 172 exposed through y a mask pattern (not shown). The first pillar layers 181 and 182 may be formed using an electro-plating process.

In order to form the first pillar layers 181 and 182, the first substrate 101 including the first seed layers 171 and 172 may be placed in a bath that facilitates the electro-plating process.

During the electro-plating process forming the first pillar layers 181 and 182, a thickness of each of the first pillar layers 181 and 182 may be varied in accordance with a planar area of each of the exposed first seed layers 171 and 172. That is, a second thickness 182H of the first pillar layer 182 formed on the first seed layer 172 may be greater than a first thickness 181H of the first pillar layer 181 formed on the first seed layer 171.

Referring to FIGS. 1B and 7D, the second substrate 201 may be prepared with the second semiconductor device layer 210, the second wiring layer 220, and second bump pads 230.

The second passivation layer 270 may be formed with openings associated with the second bump pads 230. The second passivation layer 270 may be formed as a single-layer insulation layer or a multi-layer insulation layer to cover a top surface 201T of the second substrate 201.

Second seed layers 271 and 272 may then be formed to contact exposed portions of the second bump pads 230.

Second pillar layers 281 and 282 may then be formed on the second seed layers 271 and 272. For example, using an electro-plating process to form the second pillar layers 281 and 282, a thickness for each of the second pillar layers 281 and 282 may be varied in accordance with a planar area for each of the second seed layers 271 and 272. That is, a thickness of the second pillar layer 282 formed on the second seed layer 272 may be greater than a thickness of the second pillar layer 281 formed on the second seed layer 271.

Referring to FIGS. 1B and 7E, a solder layer SB may be formed on the second pillar layers 281.

The solder layer SB may be formed on the second pillar layer 281 with a relatively thin thickness in such a manner that the resulting bump structures BS may have different shapes, as described by way of example above. Here, the solder layer SB may be formed using an electro-plating process and a reflow process.

The reflow process may be performed in a temperature range of about 220□ to about 260□. The solder layer SB may be formed by melting a solder through the reflow process. The solder should be melted but not broken down, such that a portion of the solder layer SB may formed on the pillar layer 281 as the result of surface tension, and an intermetallic compound may be formed on a boundary surface between the solder layer SB and the second pillar layer 281.

Referring to FIGS. 1B and 7F, a bottom surface 201B of the second substrate 201 covered with the adhesive layer BL may be positioned an aligned over the top surface 101T of the first substrate 101. Then, by applying pressure ‘P’ to the second substrate 201, the second semiconductor chip 200 may be connected to the first semiconductor chip 100 through the formation of the bump structures BS (e.g., first bump structures BS1 and second bump structures BS2). (See, e.g., FIG. 7G).

Here, each first pillar layer 181 and a corresponding one of the second pillar layers 281 may be connected through the intervening solder layer SB. In contrast, each first pillar layer 182 and a corresponding one of the second pillar layers 282 may be connected by direct bonding without the use of the solder layer.

Referring to FIGS. 1B and 7G, once the second semiconductor chip 200 is aligned and stacked on the first semiconductor chip 100, heat may be applied to the first and second bump structures BS1 and BS2 and the adhesive layer BL to cure the adhesive layer BL. In this manner, the second semiconductor chip 200 may be solidly attached to the first semiconductor chip 100 using first and second bump structures BS1 and BS2 having different shapes.

Subsequently, a molding member MB may be formed to cover the second semiconductor chip 200.

Using the manufacturing process described above, semiconductor packages according to embodiments of the inventive concept and including the first semiconductor chip 100, the second semiconductor chip 200, the first and second bump structures BS1 and BS2 electrically connecting the first semiconductor chip 100 to the second semiconductor chip 200, and the molding member MB may be completed, wherein such semiconductor packages exhibit improved product reliability and higher production yields.

FIG. 8 is a block diagram illustrating one possible configuration for a semiconductor package 1000 according to embodiments of the inventive concept.

Referring to FIG. 8, the semiconductor package 1000 may include a micro processing unit 1010, a memory 1020, an interface 1030, a graphics processing unit 1040, a plurality of function blocks 1050, and a bus 1060 connecting the elements.

The semiconductor package 1000 may include all of the micro processing unit 1010 and the graphics processing unit 1040, or may include only one of two elements.

The micro processing unit 1010 may include a core and a cache. For example, the micro processing unit 1010 may include a multicore. Cores of the multicore may have the same function or different functions. Also, the cores of the multicore may be simultaneously activated, or may be activated at different times.

The memory 1020 may store a result obtained processing by the function blocks 1050 on the basis of control by the micro processing unit 1010. The interface 1030 may transfer and receive information or a signal to or from external devices. The graphics processing unit 1040 may perform graphics functions. For example, the graphics processing unit 1040 may perform video codec, or may process three-dimensional (3D) graphics. The function blocks 1050 may perform various functions. For example, when the semiconductor 1000 is an application processor used in a mobile device, some of the function blocks 1050 may perform a communication function.

The semiconductor package 1000 may include any one of the semiconductor packages 10, 20, 30, 40, and 50 previously described above with reference to FIGS. 1A to 1D, 2, 3, 4, and 5.

While the inventive concept has been particularly shown and described with reference to embodiments thereof, it will be understood that various changes in form and details may be made therein without departing from the spirit and scope of the following claims.

What is claimed is:

1. A semiconductor package comprising:
a first semiconductor chip including:
a first substrate including a top surface and a bottom surface;
first through vias extending through the first substrate;
first bump pads on the top surface of the first substrate and respectively connected to the first through vias;
a first wiring layer on the bottom surface of the first substrate and connected to the first through vias; and
first pillar layers respectively on the first bump pads;
a second semiconductor chip stacked on the first semiconductor chip and including:
a second substrate including a bottom surface;
second connection pads on the bottom surface of the second substrate; and
second pillar layers respectively on the second connection pads and vertically aligned with the first pillar layers; and
bump structures connecting the first semiconductor chip and the second semiconductor chip, wherein the bump structures include first bump structures having a first shape and second bump structures having a second shape different from the first shape, and
each of the bump structures includes a one of the first pillar layers and one of the second pillar layers.

2. The semiconductor package of claim 1, wherein each first bump structure includes solder between the one of the first pillar layers and the one of the second pillar layers, and
each second bump structure includes the one of the first pillar layers directly contacting the one of the second pillar layers.

3. The semiconductor package of claim 1, wherein the one of the first pillar layers included in each of the first bump structures has a first width, and the one of the second pillar layers included in each of the second bump structures has a second width greater than the first width.

4. The semiconductor package of claim 3, wherein the first width is about 13 μm to about 15 μm, and the second width is about 50 μm to about 150 μm.

5. The semiconductor package of claim 1, wherein the one of the first pillar layers included in each of the first bump structures has a first thickness, and the one of the second pillar layers included in each of the second bump structures has a second thickness greater than the first thickness.

6. The semiconductor package of claim 5, wherein the first thickness is about 3 μm to about 5 μm, and the second thickness is about 7 μm to about 9 μm.

7. The semiconductor package of claim 1, wherein the one of the first pillar layers included in each of the first bump structures has a first planar area, and the one of the second pillar layers included in each of the second bump structures has a second planar area greater than the first planar area.

8. The semiconductor package of claim 1, wherein a first pitch between adjacent ones of the first bump structures is substantially the same as a second pitch between adjacent ones of second bump structures.

9. The semiconductor package of claim 1, wherein each of the first bump structures includes an upper first bonding interface and a lower first bonding interface, and each of the second bump structures includes a second bonding interface.

10. The semiconductor package of claim 9, wherein each of the upper first bonding interface, the lower first bonding interface, and the second bonding interface is disposed at a different level.

11. The semiconductor package of claim 1, further comprising:
first seed layers respectively between the first bump pads and the first pillar layers; and
second seed layers respectively between the second connection pads and the second pillar layers.

12. The semiconductor package of claim 1, further comprising:
an adhesive layer between the first substrate and the second substrate and surrounding side walls of the bump structures.

13. The semiconductor package of claim 1, further comprising:
a molding member on the top surface of the first substrate and surrounding side walls of the second substrate.

14. A semiconductor package comprising:
a logic chip including:
a first substrate including a top surface and a bottom surface;
first through vias extending through the first substrate;
first bump pads on the top surface of the first substrate and respectively connected to the first through vias;
a first wiring layer on the bottom surface of the first substrate and connected to the first through vias; and
first pillar layers respectively on the first bump pads;
a memory chip stacked on the logic chip and including:
a second substrate including a bottom surface;
second connection pads on the bottom surface of the second substrate; and
second pillar layers respectively on the second connection pads and vertically aligned with the first pillar layers; and
bump structures between the logic chip and the memory chip,
wherein the bump structures include first bump structures having a first shape and providing electrical connection between the logic chip and the memory chip, and second bump structures having a second shape different from the first shape and providing heat transfer from at least one of the logic chip and the memory chip, and
each of the bump structures includes a one of the first pillar layers and one of the second pillar layers.

15. The semiconductor package of claim 14, wherein each first bump structure communicates at least one of a control signal, a data signal, and a power signal.

16. The semiconductor package of claim 14, wherein an arrangement of the first bump structures is centrally disposed between the first substrate and the second substrate, and the second bump structures laterally bracket the arrangement of the first bump structures.

17. The semiconductor package of claim 14, wherein first bump structures and second bump structures are alternatingly arranged in a first arrangement in a first row, and
first bump structures and second bump structures are alternatingly arranged in a second arrangement offset from the first arrangement in a second row.

18. A semiconductor package comprising:
a first semiconductor chip including:
a first substrate including a top surface and a bottom surface;
first through vias extending through the first substrate;
first bump pads on the top surface of the first substrate and respectively connected to the first through vias;
a first passivation layer on the top surface of the first substrate and selectively exposing respective portions of the first bump pads through first open holes and second open holes larger than the first open holes;
a first wiring layer on the bottom surface of the first substrate and connected to the first through vias;
first seed layers on exposed portions of the first bump pads and portions of the first passivation layer; and
first pillar layers respectively on the first seed layers;
a second semiconductor chip stacked on the first semiconductor chip and including:
a second substrate including a bottom surface;
second connection pads on the bottom surface of the second substrate;
a second passivation layer on the bottom surface of the second substrate and selectively exposing respective portions of the connection pads;
second seed layers on exposed portions of the second connection pads and portions of the second passivation layer; and
second pillar layers respectively on the second seed layers; and
bump structures connecting the first semiconductor chip and the second semiconductor chip, wherein the bump structures include first bump structures having a first shape defined by the first open holes and second bump structures having a second shape defined by the second open holes, and
each of the bump structures includes a one of the first pillar layers and one of the second pillar layers.

19. The semiconductor package of claim 18, further comprising:
first connection pads on the bottom surface of the first substrate and electrically connecting the first wiring layer;
first connection terminals respectively on the first connection pads;
a second wiring layer on the bottom surface of the second substrate; and
second through vias extending through the second substrate and electrically connecting the second wiring layer and the second connection pads.

20. The semiconductor package of claim 18, wherein the one of the first pillar layers included in each of the first bump structures has a first width, and the one of the second pillar layers included in each of the second bump structures has a second width greater than the first width,
the one of the first pillar layers included in each of the first bump structures has a first thickness, and the one of the second pillar layers included in each of the second bump structures has a second thickness greater than the first thickness,
the one of the first pillar layers included in each of the first bump structures has a first planar area, and the one of the second pillar layers included in each of the second bump structures has a second planar area greater than the first planar area,
each of the first bump structures includes an upper first bonding interface and a lower first bonding interface,
each of the second bump structures includes a second bonding interface, and
each of the upper first bonding interface, the lower first bonding interface, and the second bonding interface is disposed at a different level.
